(19) United States
(12) Patent Application Publication
(10) Pub. No.: US 2015/0243786 A1
(43) Pub. Date: Aug. 27, 2015

(54) SEMICONDUCTOR DEVICE AND MANUFACTURING METHOD THEREOF

(71) Applicant: KABUSHIKI KAISHA TOSHIBA, Tokyo (JP)

(72) Inventor: Masakazu GOTO, Yokohama-Shi (JP)

(73) Assignee: KABUSHIKI KAISHA TOSHIBA, Tokyo (JP)

(21) Appl. No.: 14/288,097

(22) Filed: May 27, 2014

Related U.S. Application Data
(60) Provisional application No. 61/943,220, filed on Feb. 21, 2014.

(51) Int. Cl. H01L 29/78; H01L 29/417

(52) U.S. Cl. CPC H01L 29/7843; H01L 29/41783; H01L 29/7835

(57) ABSTRACT

A semiconductor device according to an embodiment includes a first conductivity-type first source layer provided in a semiconductor layer. A second conductivity-type drain layer is provided in the semiconductor layer. A gate dielectric film is provided on the semiconductor layer between the first source layer and the drain layer. A first gate structure is provided on the gate dielectric film. A drain-side adjacent structure is adjacent to the first gate structure on a side of the drain layer of the first gate structure. A stress layer covers at least the first gate structure, the drain-side adjacent structure, and the first source layer. The stress layer has strain. A first gap between the first gate structure and the drain-side adjacent structure is narrower than four times a film thickness of the stress layer. The stress layer covers the first source layer along a channel-direction longer than the first gap.

### CROSS REFERENCE TO RELATED APPLICATIONS

This application is based upon and claims the benefit of priority from the prior U.S. Provisional Patent Application No. 61/943,220, filed on Feb. 21, 2014, the entire contents of which are incorporated herein by reference.

### FIELD

The embodiments of the present invention relate to a semiconductor device and manufacturing method thereof.

### BACKGROUND

In recent years, a TFET (Tunnel Field-Effect Transistor) that employs a quantum-mechanical effect of electrons has been developed. In the TFET, by applying a voltage to a gate electrode, BTBT (Band To Band Tunneling) is caused between a source and a channel. As a result, the TFET becomes an on-state.

To increase an on-state current of a TFET, it is effective to introduce strain in a substrate. By introducing strain in a substrate, a bandgap of the substrate becomes narrow and effective mass of conductive carrier is reduced. Tunneling efficiency is thus improved, which increases the on-state current.

In a TFET, the on-state current is determined by tunneling efficiency on the side of a source. Meanwhile, an off-state current is determined by tunneling efficiency on the side of a drain. Therefore, if uniform strain is applied to the side of a source and the side of a drain, there is a problem that not only the on-state current but also the off-state current is increased.

### BRIEF DESCRIPTION OF THE DRAWINGS

FIG. 1 is a plan view showing an example of a configuration of a TFET 100 according to a first embodiment;

FIG. 2 is a cross-sectional view along a line 2-2 of FIG. 1;

FIG. 3 is a graph of relationships between the density of a layout pattern of a gate structure and a drain current Id;

FIG. 4 is a cross-sectional view showing the TFET 100 that includes a shallow trench isolation region STI in the source layers S1 and S2;

FIGS. 5A to 7B are cross-sectional views of an example of a manufacturing method of the TFET 100 according to the first embodiment;

FIG. 8 is a plan view showing an example of a configuration of a TFET 110 according to a modification of the first embodiment;

FIG. 9 is a cross-sectional view showing an example of a configuration of a TFET 200 according to a second embodiment;

FIGS. 10A to 11B are cross-sectional views of an example of a manufacturing method of the TFET 200 according to the second embodiment;

FIG. 12 is a cross-sectional view showing an example of a configuration of a TFET 300 according to a third embodiment; and

FIG. 13 is a cross-sectional view showing an example of a configuration of a TFET 310 according to a modification of the third embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor layer on which semiconductor elements are provided is assumed as “an upper direction”. Therefore, the term “upper direction” or “lower direction” occasionally differs from an upper direction or a lower direction based on a gravitational acceleration direction.

A semiconductor device according to an embodiment includes a semiconductor layer. A first conductivity-type first source layer is provided in the semiconductor layer. A second conductivity-type drain layer is provided in the semiconductor layer. A gate dielectric film is provided on the semiconductor layer between the first source layer and the drain layer. A first gate structure is provided on the gate dielectric film. A drain-side adjacent structure is adjacent to the first gate structure on a side of the drain layer of the first gate structure. A stress layer covers at least the first gate structure, the drain-side adjacent structure, and the first source layer. The stress layer has strain. A first gap between the first gate structure and the drain-side adjacent structure is narrower than four times a film thickness of the stress layer. The stress layer covers the first source layer along a channel direction longer than the first gap.

### First Embodiment

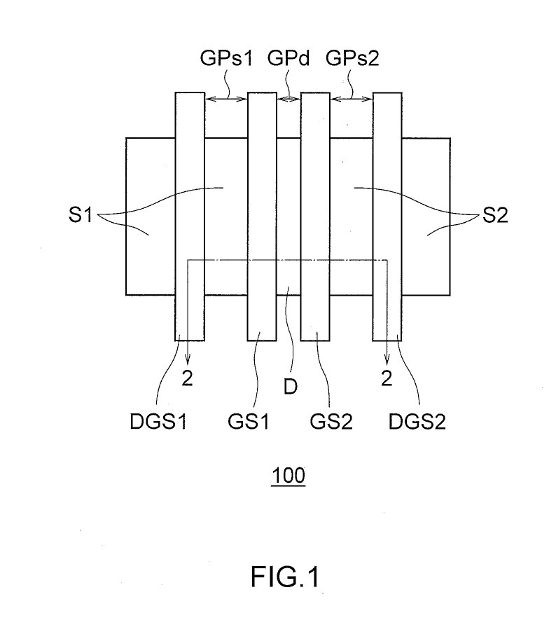

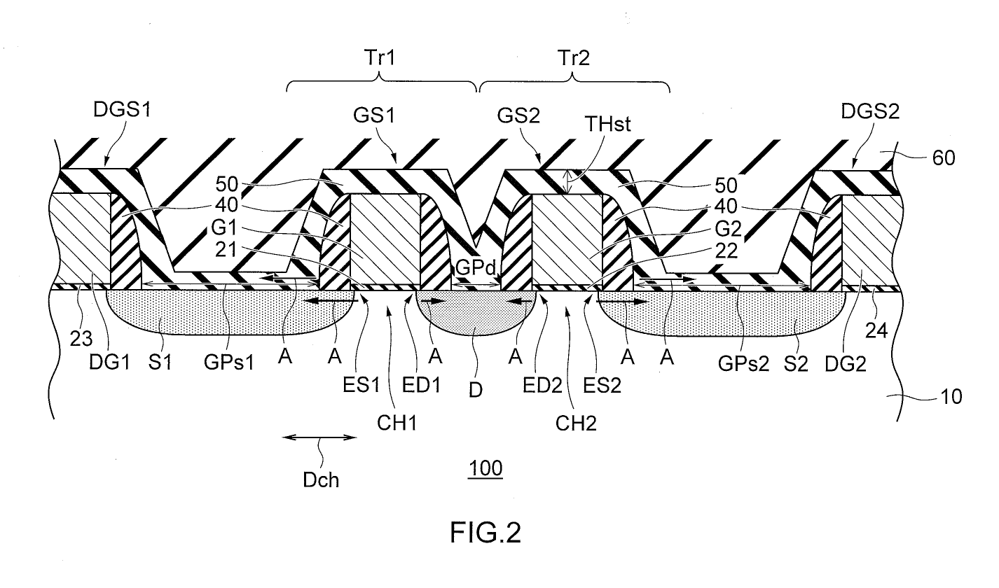

FIG. 1 is a plan view showing an example of a configuration of a TFET 100 according to a first embodiment. FIG. 2 is a cross-sectional view along a line 2-2 of FIG. 1. The TFET 100 can be used for microprocessors or logic semiconductor integrated circuits such as an ASIC (Application Specific Integrated Circuit).

As shown in FIG. 2, the TFET 100 includes a semiconductor layer 10, source layers S1 and S2, a drain layer D, gate dielectric films 21 to 24, gate electrodes G1 and G2, dummy gate electrodes DG1 and DG2, a sidewall film 40, a stress layer 50, and an interlayer dielectric film 60.

The semiconductor layer 10 can be a semiconductor substrate such as a silicon substrate or can be an SOI (Silicon On Insulator) layer on a BOX layer.

The p-type (first conductivity type) source layers S1 and S2 are formed on surface regions of the semiconductor layer 10. The n-type (second conductivity type) drain layer D is formed on another surface region of the semiconductor layer 10. The source layers S1 and S2 are formed by implanting a p-type impurity (for example, boron) in the semiconductor layer 10. The drain layer D is formed by implanting an n-type impurity (for example, arsenic or phosphorus) in the semiconductor layer 10. The source layer S1 is formed on a surface region of the semiconductor layer 10 on the side of the gate electrode G1 opposite to the drain layer D. The source layer S2 is formed on a surface region of the semiconductor layer 10 on the side of the gate electrode G2 opposite to the drain layer D.

The gate dielectric film 21 is provided between the drain layer D and the source layer S1 on the semiconductor layer 10. The gate dielectric film 22 is provided between the drain layer D and the source layer S2 on the semiconductor layer 10. For example, the gate dielectric films 21 and 22 are formed of a silicon oxide film, a silicon oxynitride film, or a dielectric film having a higher dielectric constant than that of the silicon oxide film (for example, HfO₂).

The gate electrode G1 is provided on the gate dielectric film 21. The gate electrode G2 is provided on the gate dielectric film 22. For example, the gate electrodes G1 and G2 are formed of a conductive material such as doped polysilicon. The sidewall film 40 is provided on side surfaces of the gate electrodes G1 and G2.

For example, the sidewall film 40 is formed of an insulation film such as a silicon oxide film. According to the first embodiment, a gate structure GS1 is a structure that includes the gate electrode G1, and the sidewall film 40 on a side surface of the gate electrode G1. A gate structure GS2 (drain-side adjacent structure) is a structure that includes the gate electrode G2, and the sidewall film 40 on a side surface of the gate electrode G2.

The stress layer 50 is provided so as to cover the gate electrodes G1 and G2, the source layers S1 and S2, the drain layer D, and the sidewall film 40. The stress layer 50 includes strain therein and applies a stress to a part contacting the stress layer 50. For example, the stress layer 50 is formed of an insulation film such as a silicon nitride film and applies a stress to the source layers S1 and S2. The stress layer 50 such as a silicon nitride film can have a tensile stress or a compressive stress depending on a temperature at which the stress layer 50 is formed. As explained later, the stress layer 50 also functions as an etching stopper at a contact forming process.

The interlayer dielectric film 60 is provided on the stress layer 50. For example, the interlayer dielectric film 60 is an insulation film such as a silicon oxide film using TEOS (Tetraethylorthosilicate).

A transistor Tr1 includes the gate electrode G1, the source layer S1, and the drain layer D. A transistor Tr2 includes the gate electrode G2, the source layer S2, and the drain layer D. The transistors Tr1 and Tr2 are adjacent to each other and share the drain layer D. CH1 is a channel part of the transistor Tr1 and CH2 is a channel part of the transistor Tr2.

The dummy gate electrodes DG1 and DG2 are formed simultaneously with the gate electrodes G1 and G2, and have a configuration identical to that of the gate electrodes G1 and G2. As shown in FIG. 2, the dummy gate electrodes DG1 and DG2 are formed on the gate dielectric films 23 and 24 on the semiconductor layer 10, respectively. The dummy gate electrodes DG1 and DG2 are provided to reduce the difference in the density of gate electrodes in a layout. By reducing the difference in the density of gate electrodes in a layout, the processing variation of gate electrodes can be reduced. Unlike the gate electrodes G1 and G2, the dummy gate electrodes DG1 and DG2 are not electrically driven. Therefore, the dummy gate electrodes DG1 and DG2 are held at a fixed potential or in a potentially floating state.

A dummy gate structure DGS1 (first source-side adjacent structure) is a structure that includes the dummy gate electrode DG1, and the sidewall film 40 on a side surface of the dummy gate electrode DG1. A dummy gate structure DGS2 (second source-side adjacent structure) is a structure that includes the dummy gate electrode DG2, and the sidewall film 40 on a side surface of the dummy gate electrode DG2.

Although not shown in the drawings, a contact with the drain layer D is provided between the gate electrodes G1 and G2. Contacts with the source layers S1 and S2 are provided between the gate electrode G1 and the dummy gate electrode DG1 and between the gate electrode G2 and the dummy gate electrode DG2, respectively.

When it is assumed that the gate structure GS1 is a first gate structure, as shown in FIGS. 1 and 2, the dummy gate structure DGS1 is a first source-side adjacent structure that is adjacent to the gate structure GS1 on the side of the source layer S1 of the gate structure GS1. The gate structure GS2 is a drain-side adjacent structure that is adjacent to the gate structure GS1 on the side of the drain layer D of the gate structure GS1. Further, the dummy gate structure DGS2 is a second source-side adjacent structure that is adjacent to the gate structure GS2 on the side of the source layer S2 of the gate structure GS2.

A gap GPd (first gap) between the gate structure GS1 and the gate structure GS2 is narrower than a gap GPs1 (second gap) between the gate structure GS1 and the dummy gate structure

DGS1. In addition, the gap GPd is narrower than a gap GPs2 (third gap) between the gate structure GS2 and the dummy gate structure DGS2. For example, the gaps GPs1 and GPs2 are wider than four times a film thickness THst of the stress layer 50 (see FIG. 2). Meanwhile, the gap GPd is narrower than four times the film thickness THst of the stress layer 50. The stress layer 50 covers the gate structures GS1 and GS2, the dummy gate structures DGS1 and DGS2, the source layers S1 and S2, and the drain layer D. As a result, the stress layer 50 covers the source layers S1 and 52 along a channel direction Dch of the transistors Tr1 and Tr2 shown in FIG. 2 longer than the gap GPd. Further, to increase a stress to the source layers S1 and S2, the length of the stress layer 50 that covers the source layers S1 and S2 along the channel direction Dch is preferably longer than four times the film thickness THst of the stress layer 50.

Because the gap GPd is narrower than the gaps GPs1 and GPs2, a stress applied by the stress layer 50 to the drain layer D is smaller than that applied by the stress layer 50 to the source layers S1 and S2. That is, because the gap GPd is narrow, the stress layer 50 is blocked on the drain layer D, and thus the stress applied by the stress layer 50 to the drain layer D becomes relatively small. On the other hand, because the gaps GPs1 and GPs2 are wider than the gap GPd, the stress layer 50 is not blocked on the source layers S1 and S2. Therefore, the stress applied by the stress layer 50 to the source layers S1 and S2 is relatively large. In this manner, strain of the stress layer 50 is applied to the source layers S1 and S2 as a relatively large stress, but is hardly applied to the drain layer D as a stress. Arrows A in FIG. 2 show directions and intensity of a stress, for example, when a tensile stress is applied by the stress layer 50.

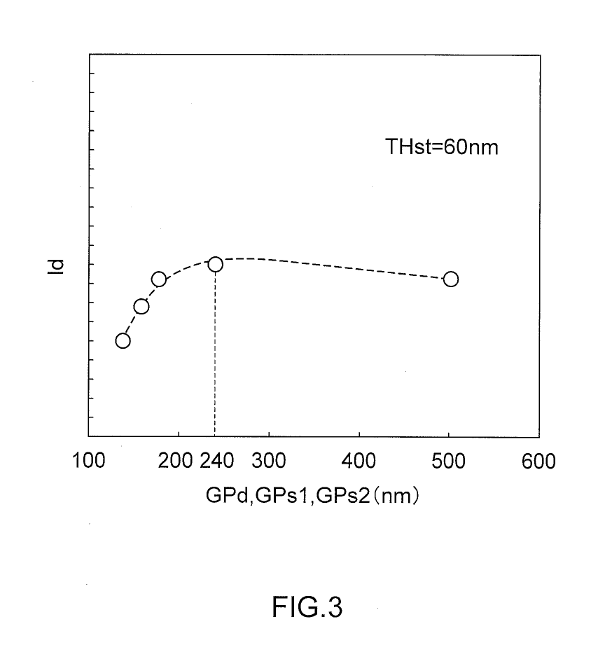

FIG. 3 is a graph of relationships between the density of a layout pattern of a gate structure and a drain current Id. In the graph of FIG. 3, the horizontal axis indicates a space gap between the gate structure GS1 and the dummy gate structure DGS1 or between the gate structure GS2 and the dummy gate structure DGS2 (a gate-to-gate pitch or a gate-to-dummy-gate pitch) in the TFET 100. The vertical axis indicates the drain current Id of the TFET 100. For example, this space gap corresponds to the gap GPS1, GPS2, or GPd shown in FIG. 1. For example, the drain current Id corresponds to a current flowing between the source layer S1 and the drain layer D in the transistor Tr1 or between the source layer S2 and the drain layer D in the transistor Tr2. The drain current Id is influenced by a stress (strain) applied to the channel parts CH1 and CH2, the source layers S1 and S2, or the drain layer D (hereinafter, also “channel part and the like”). When the stress layer 50 applies a large stress to the channel part and the like, the drain current Id is increased. The film thickness THst of the stress layer 50 is about 60 nanometers (nm).

It is understood from the graph of FIG. 3 that when the space gap is less than about 240 nm, the drain current Id is reduced. This means that when the space gap is less than about 240 nm and the stress layer 50 is blocked, it is difficult for effects of strain of the stress layer 50 to be transmitted to the channel part and the like. That is, when the space gap is less than about 240 nm, it is difficult to apply a stress from the stress layer 50 to the channel part and the like.

Whether the stress layer 50 is blocked between gate structures or between a gate structure and a dummy gate structure also depends on the film thickness THst of the stress layer 50. For example, when the film thickness THst of the stress layer 50 is small, the stress layer 50 is difficult to be blocked even though the space gap is relatively narrow. On the other hand, when the film thickness THst of the stress layer 50 is large, the stress layer 50 is easily blocked even though the space gap is relatively wide. Therefore, a stress applied by the stress layer 50 of the TFET 100 to the channel part and the like depends on not only the space gap but also the film thickness THst of the stress layer 50.

The graph of FIG. 3 shows that when the film thickness THst of the stress layer 50 is about 60 nm, the critical value of the space gap is about 240 nm. This means that the critical value of the space gap is about four times the film thickness of the stress layer 50. For example, when the space gap is equal to or more than about four times the film thickness of the stress layer 50, a stress from the stress layer 50 is easily applied to the channel part and the like. When the space gap is less than about four times the film thickness of the stress layer 50, a stress from the stress layer 50 is difficult to be applied to the channel part and the like.

According to the first embodiment, such relationships between the space gap and the intensity of a stress are used to control stresses applied to the channel parts CH1 and CH2, the source layers S1 and S2, and the drain layer D. For example, as explained above, the gap GPd is narrower than four times the film thickness THst of the stress layer 50. Meanwhile, the source layers S1 and S2 are covered by the stress layer 50 along the channel direction Dch longer than the gap GPd. Therefore, the stress layer 50 is blocked on the drain layer D and a stress applied to the drain layer D is smaller than that applied to the source layers S1 and S2. That is, when the gap GPd is narrower than four times the film thickness THst of the stress layer 50, a relatively small stress is applied to a drain-side channel part (a boundary ED1 between the drain layer D and the channel CH1 and a boundary ED2 between the drain layer D and the channel CH2). On the other hand, when the gaps GPs1 and GPs2 are wider than four times the film thickness THst of the stress layer 50, a relatively large stress is applied to a source-side channel part (a boundary ES1 between the source layer S1 and the channel CH1 and a boundary ES2 between the source layer S2 and the channel CH2). As a result, the stress applied to the source layers S1 and S2 is larger than the stress applied to the drain layer D. In the following descriptions, ED1 and ED2 are also referred to as “drain edge”, and ES1 and ES2 are also referred to as “source edge”.

As explained above, in the TFET 100, an on-state current is determined by tunneling efficiency on the side of the source layers S1 and S2. On the other hand, an off-state current is determined by tunneling efficiency on the side of the drain layer D. The tunneling efficiency on the side of the source layers S1 and S2 depends on the stress applied to the source layers Si and S2 (the source edges ES1 and ES2). On the other hand, the tunneling efficiency on the side of the drain layer D depends on the stress applied to the drain layer D (the drain edges ED1 and ED2). Therefore, the stress applied to the source layers S1 and S2 (the source edges ES1 and ES2) is larger than the stress applied to the drain layer D (the drain edges ED1 and ED2) and thus the TFET 100 according to the first embodiment can increase an on-state current while suppressing an increase in an off-state current. A stress applied by the stress layer 50 to the source layers S1 and S2 or the drain layer D can be a tensile stress or a compressive stress.

Further, when the gaps GPs1 and GPs2 are wider than four times the film thickness THst of the stress layer 50, a much higher stress from the stress layer 50 can be applied to the source layers S1 and S2. As a result, a stress applied to the source edges ES1 and ES2 is much larger than that applied to the drain edges ED1 and ED2 and the difference between these stresses also becomes large. Therefore, the TFET 100 can further increase an on-state current while suppressing an increase in an off-state current.

According to the first embodiment, the drain layer D is shared by the transistors Tr1 and Tr2. However, it is possible to provide a shallow trench isolation region (not shown) in the drain layer D to electrically isolate a drain layer of the transistor Tr1 from a drain layer of the transistor Tr2.

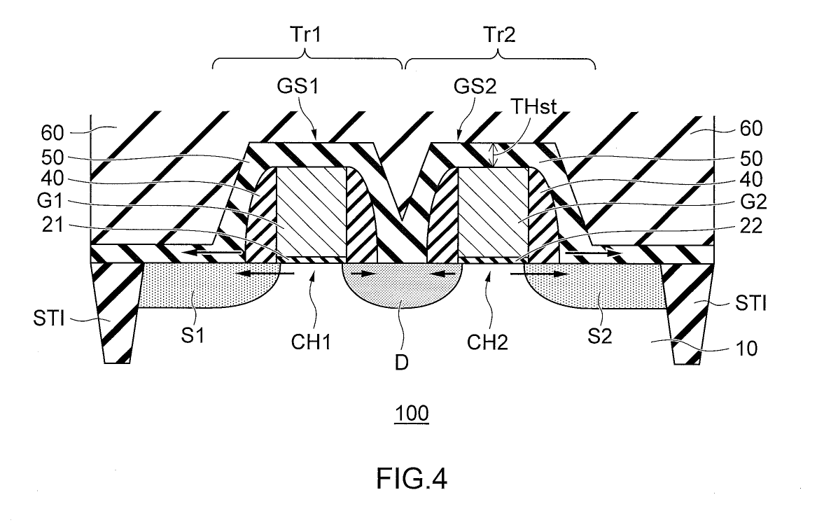

According to the first embodiment, as shown in FIG. 1, the dummy gate structures DGS1 and DGS2 are provided on the source layers S1 and S2, respectively. However, as shown in FIG. 4, the dummy gate structures DGS1 and DGS2 are not necessarily provided.

FIG. 4 is a cross-sectional view showing the TFET 100 that includes a shallow trench isolation region STI in the source layers S1 and S2. Even though the dummy gate structures DGS1 and DGS2 are not provided, the gap GPd can be narrower than four times the film thickness THst of the stress layer 50 and the gaps GPs1 and GPs2 can be wider than the gap GPd. Therefore, the stress layer 50 can cover the source layers S1 and S2 along the channel direction Dch longer than the gap GPd, and can apply a stress larger than that applied to the drain layer D to the source layers S1 and S2. In this case, as shown in FIG. 4, the shallow trench isolation region STI can be provided around the TFET 100. In FIG. 4, one of the gate structures GS1 and GS2 can be a dummy gate structure.

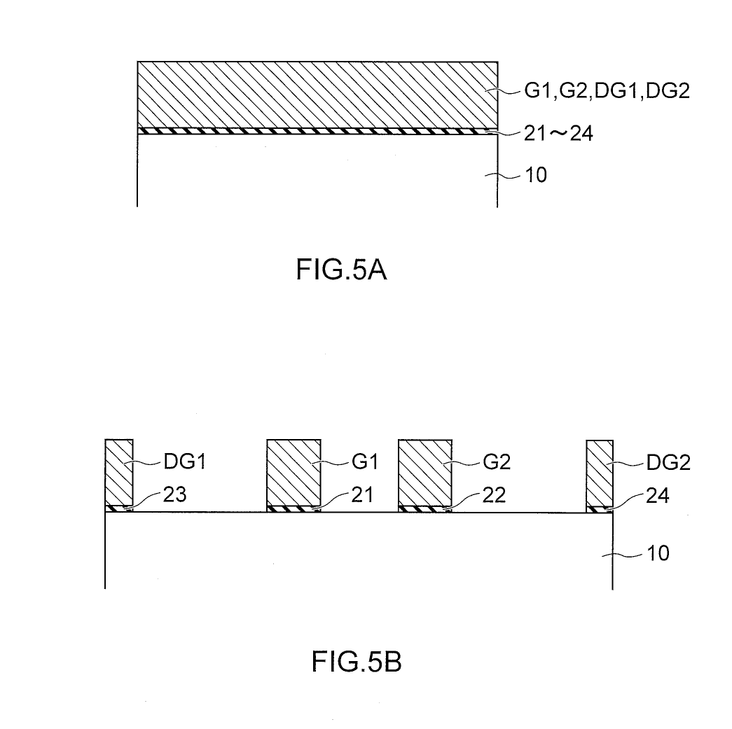

FIGS. 5A to 7B are cross-sectional views of an example of a manufacturing method of the TFET 100 according to the first embodiment. As shown in FIG. 5A, a material for the gate dielectric films 21 to 24 is formed first on the semiconductor layer 10. As explained above, the material for the gate dielectric films 21 to 24 is formed of a silicon oxide film, a silicon oxynitride film, or a dielectric film having a higher dielectric constant than that of the silicon oxide film (for example, HfO₂).

Next, a material for the gate electrodes G1 and G2 and the dummy gate electrodes DG1 and DG2 is deposited on the material for the gate dielectric films 21 to 24 by a CVD (Chemical Vapor Deposition) method. For example, the material for the gate electrodes G1 and G2 and the dummy gate electrodes DG1 and DG2 is polysilicon and the like. Next, for example, an n-type impurity is implanted in the material for the gate electrodes G1 and G2 and the dummy gate electrodes DG1 and DG2 by an ion implantation method. As a result, the material for the gate electrodes G1 and G2 and the dummy gate electrodes DG1 and DG2 becomes conductive doped polysilicon.

Next, the material for the gate electrodes G1 and G2 and the dummy gate electrodes DG1 and DG2 and the material for the gate dielectric films 21 to 24 are processed by a lithographic technique and an etching technique. As a result, as shown in FIG. 5B, the gate electrodes G1 and G2, the dummy gate electrodes DG1 and DG2, and the gate dielectric films 21 to 24 are formed. At this time, a gap between the gate electrodes G1 and G2 is formed to be narrower than a gap between the gate electrode G1 and the dummy gate electrode DG1 and a gap between the gate electrode G2 and the dummy gate electrode DG2.

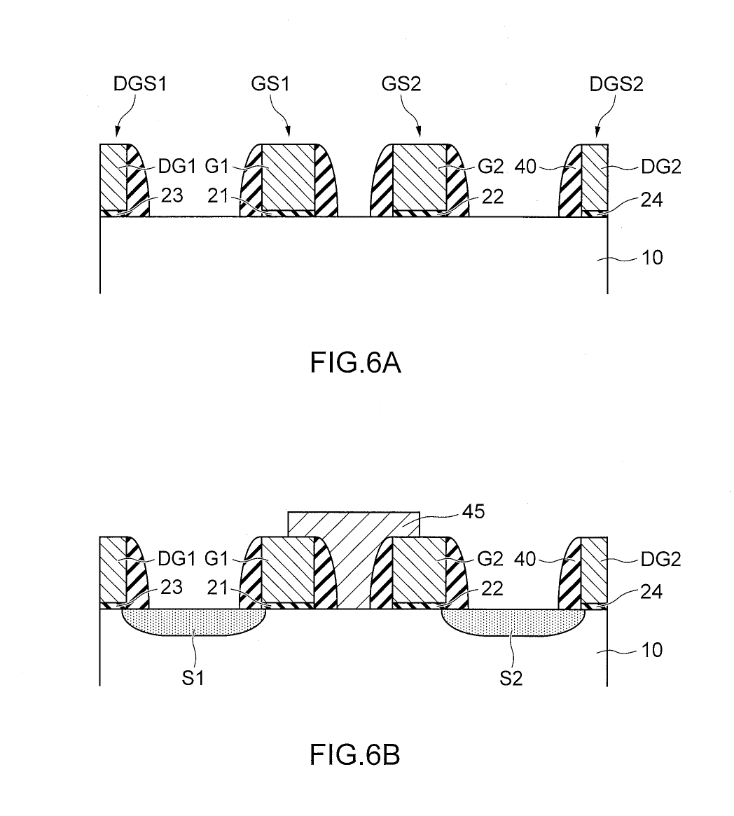

Next, a material for the sidewall film 40 is deposited on top surfaces and on side surfaces of the gate electrodes G1 and G2 and the dummy gate electrodes DG1 and DG2 and on the semiconductor layer 10 by the CVD method. For example, the material for the sidewall film 40 is an insulation film such as a silicon oxide film. For example, the film thickness of the material of the sidewall film 40 is about 30 nm. Next, the sidewall film 40 is anisotropically etched by an RIE (Reactive Ion Etching) method. As a result, as shown in FIG. 6A, the sidewall film 40 remains on the respective side surfaces of the gate electrodes G1 and G2 and the dummy gate electrodes DG1 and DG2. In this manner, the gate structures GS1 and GS2 and the dummy gate structures DGS1 and DGS2 are formed. The dummy gate structure DGS1 is adjacent to the gate structure GS1 on the side of the source layer S1 of the gate structure GS1. The gate structure GS2 is adjacent to the gate structure GS1 on the side of the drain layer D of the gate structure GS1. The dummy gate structure DGS2 is adjacent to the gate structure GS2 on the side of the source layer S2 of the gate structure GS2.

Next, as shown in FIG. 6B, a region where the drain layer D is formed (the semiconductor layer 10) is covered by a resist film 45 by the lithographic technique. Next, a p-type impurity is implanted in regions where the source layers S1 and S2 are formed (the semiconductor layer 10) by using the resist film 45 as a mask. This p-type impurity is, for example, BF₂.

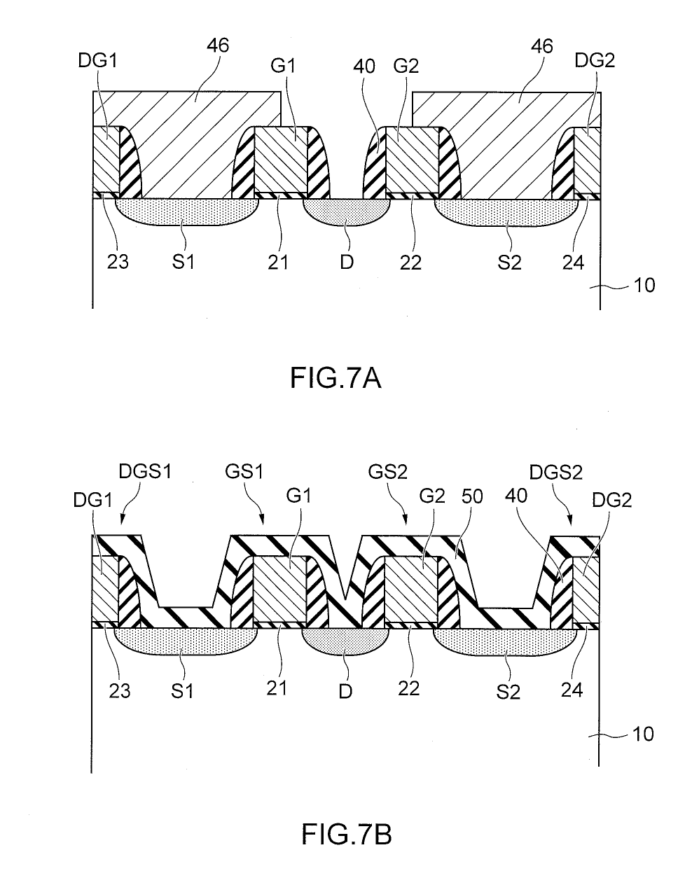

Next, after the resist film 45 is removed, the regions where the source layers S1 and S2 are formed are covered by a resist film 46 by the lithographic technique as shown in FIG. 7A. Next, an n-type impurity is implanted in the drain layer D by using the resist film 46 as a mask. This n-type impurity is, for example, As or P.

After the resist film 46 is removed, the semiconductor layer 10 is thermally processed to activate the impurities of the source layers S1 and S2 and the drain layer D. This thermal process is, for example, a spike annealing method at a temperature of about 1025° C.

Next, as shown in FIG. 7B, the stress layer 50 is formed on the gate structures GS1 and GS2, the dummy gate structures DGS1 and DGS2, the source layers S1 and S2, and the drain layer D. For example, the stress layer 50 is an insulation film such as a silicon nitride film. When the stress layer 50 is a silicon nitride film, by adjusting a temperature at the time of forming the stress layer 50, the stress layer 50 can have a tensile stress or a compressive stress.

Next, the interlayer dielectric film 60 is deposited on the stress layer 50. Thereafter, contact plugs, wires, other interlayer dielectric films, and the like (not shown) are formed on the interlayer dielectric film 60, thereby completing the TFET 100 shown in FIG. 2. When contact holes are formed in the interlayer dielectric film 60, the stress layer 50 functions as an etching stopper.

It suffices shallow trench isolation regions STI shown in FIG. 4 are formed in the semiconductor layer 10 before the gate dielectric films 21 to 24 are formed. For example, a trench is formed in the semiconductor layer 10 by the lithographic technique and the etching technique. Next, an insulation film such as a silicon oxide film is embedded into this trench, thereby forming the shallow trench isolation regions STI. Thereafter, with the processes explained with reference to FIGS. 5A to 7B, the TFET 100 shown in FIG. 4 is obtained.

According to the first embodiment, with a difference between the gap GPd from the gate structure GS1 to the gate structure GS2 and the gap GPs1 (or GPs2) from the gate structure GS1 (or GS2) to the dummy gate structure DGS1 (or DGS2), stresses applied to the source layers S1 and S2 and the drain layer D can be controlled asymmetrically. For example, as shown in FIGS. 1 and 2, the gap GPd is formed to be narrower than four times the film thickness THst of the stress layer 50, and the gaps GPs1 and GPs2 are formed to be wider than the gap GPd. Accordingly, the stress layer 50 is blocked on the drain layer D and a stress applied to the drain layer D (the drain edges ED1 and ED2) is smaller than that applied to the source layer S1, S2 (the source edges ES1 and ES2). As a result, tunneling efficiency on the side of the source layers 51 and S2 that determines an on-state current can be improved without increasing tunneling efficiency on the side of the drain layer D that determines an off-state current. Therefore, the on-state current can be increased while an increase in the off-state current is suppressed in the TFET 100.

Furthermore, when the gaps GPs1 and GPs2 are wider than four times the film thickness THst of the stress layer 50, a much higher stress from the stress layer 50 can be applied to the source layers S1 and S2. A stress applied to the source edges ES1 and ES2 is thus much larger than that applied to the drain edges ED1 and ED2, and the difference between these stresses also becomes noticeable. As a result, the on-state current can be increased while an increase in the off-state current is suppressed in the TFET 100.

### Modification

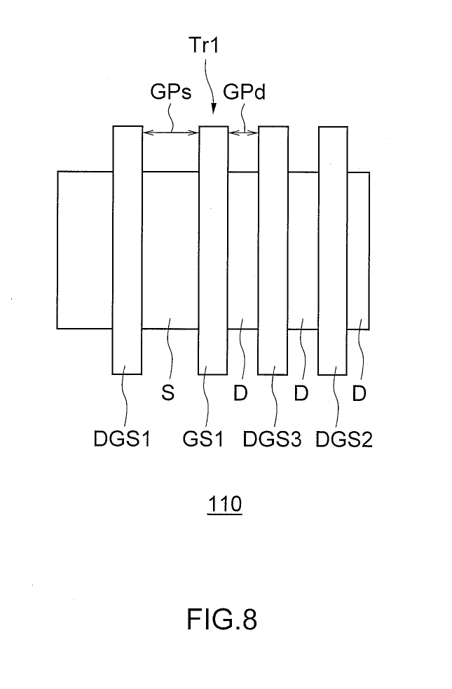

FIG. 8 is a plan view showing an example of a configuration of a TFET 110 according to a modification of the first embodiment.

The TFET 110 according to the present modification has one transistor Tr1 and has a dummy gate structure DGS3 instead of the gate structure GS2. The drain layer D is formed on the region of the source layer S2 shown in FIG. 1. Other configurations of the present modification can be identical to corresponding ones of the first embodiment.

The TFET 110 includes the gate structure GS1 and the dummy gate structures DGS1 to DGS3. The gate structure GS1, the dummy gate structure DGS1, and the dummy gate structure DGS2 can be identical to those of the first embodiment. The dummy gate structure DGS2 is provided on the drain layer D. The dummy gate structure DGS3 is provided on the drain layer D and adjacent to the gate structure GS1 on the side of the drain layer D of the gate structure GS1.

While the dummy gate structure DGS3 is formed as a dummy gate, the layout thereof can be identical to that of the gate structure GS2 according to the first embodiment. Therefore, with a difference between the gap GPd from the gate structure GS1 to the dummy gate structure DGS3 and the gap GPs from the gate structure GS1 to the dummy gate structure DGS1, stresses applied to the source layer S and the drain layer D can be controlled. For example, the gap GPd is formed to be narrower than four times the film thickness THst of the stress layer 50 and the gap GPs is formed to be wider than the gap GPd. Accordingly, the stress layer 50 is blocked on the drain layer D and a stress applied to the drain layer D is smaller than that applied to the source layer S. As a result, an on-state current can be increased while an increase in an off-state current is suppressed in the TFET 110.

Further, when the gap GPs is formed to be wider than four times the film thickness THst of the stress layer 50, a much higher stress from the stress layer 50 can be applied to the source layer S.

Accordingly, the stress applied to the source layer S is much larger than the stress applied to the drain layer D, and the difference between these stresses also becomes large.

Because the manufacturing method of the TFET 110 according to the present modification can be easily understood based on the manufacturing method of the TFET 100 according to the first embodiment, explanations thereof will be omitted.

### Second Embodiment

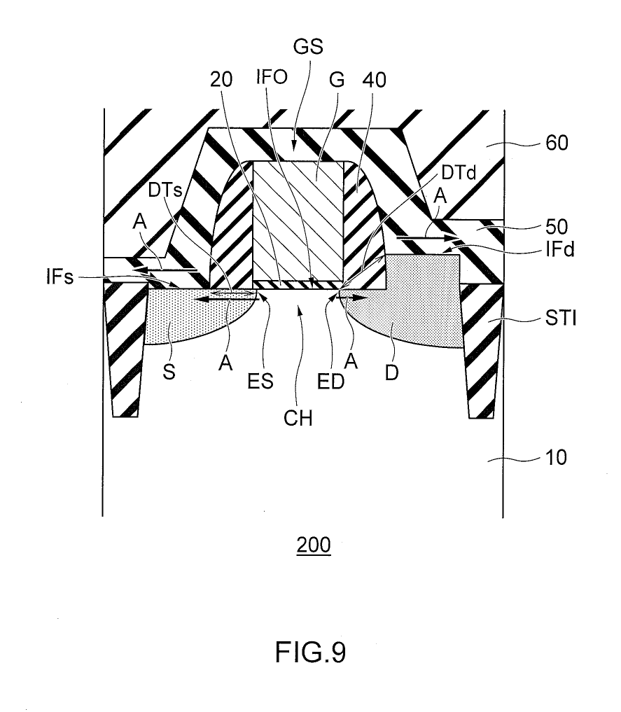

FIG. 9 is a cross-sectional view showing an example of a configuration of a TFET 200 according to a second embodiment. According to the second embodiment, the drain layer D protrudes from an interface IFO between the semiconductor layer 10 (the channel part CH) and the gate dielectric film 20. The height of a top surface of the source layer S is substantially equal to that of the interface IFO. Therefore, the height of an interface IFd between the drain layer D and the stress layer 50 is higher than the height of an interface IFs between the source layer S and the stress layer 50. In this manner, according to the second embodiment, a stress is controlled not by a layout of a gate structure and a dummy gate structure but by the height of the interfaces IFd and IFs. Therefore, according to the second embodiment, stresses applied to the source layer S and the drain layer D can be controlled even by a single gate structure GS. FIG. 9 shows only a single gate structure GS.

The TFET 200 includes the semiconductor layer 10, the source layer S, the drain layer D, the gate structure GS, the stress layer 50, the interlayer dielectric film 60, and the shallow trench isolation region STI. The configurations of the semiconductor layer 10, the gate structure GS, the stress layer 50, the interlayer dielectric film 60, and the shallow trench isolation region STI can be identical to those of the first embodiment. The source layer S can be identical to the source layer S1 or S2 according to the first embodiment. The gate dielectric film 20 can be identical to any of the gate dielectric films 21 to 24 according to the first embodiment.

According to the second embodiment, the height of the interface IFd between the drain layer D and the stress layer 50 is higher than that of the interface IFs between the source layer S and the stress layer 50. This height is a height set by using the interface IFO between the semiconductor layer 10 (a surface of the channel part CH) and the gate dielectric film 20 as a reference.

Because the height of the interface IFd is higher than that of the interface IFs, a distance DTd between the interface IFd and the channel part CH is larger (longer) than a distance DTs between the interface IFs and the channel part CH. In other words, a boundary (a drain edge) ED between the drain layer D and the channel part CH is farther from the stress layer 50 than a boundary (a source edge) ES between the source layer S and the channel part CH. Therefore, an influence of a stress of the stress layer 50 is relatively large on the source layer S and relatively small on the drain layer D. That is, a stress applied to the drain layer D is smaller than that applied to the source layer S. Arrows “A” show directions and intensity of a stress, for example, when a tensile stress is applied by the stress layer 50. Therefore, tunneling efficiency on the side of the source layer S that determines an on-state current can be improved without increasing tunneling efficiency on the side of the drain layer D that determines an off-state current. As a result, the second embodiment can also achieve effects identical to those of the first embodiment.

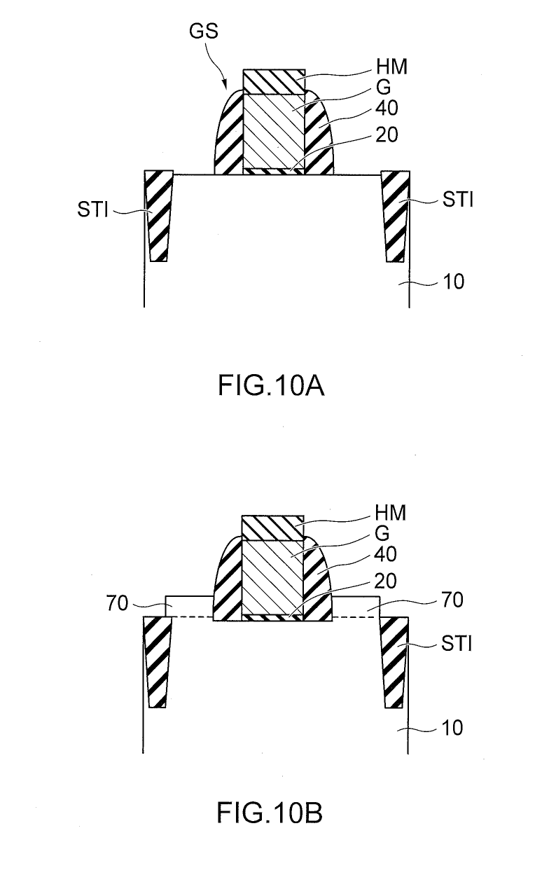

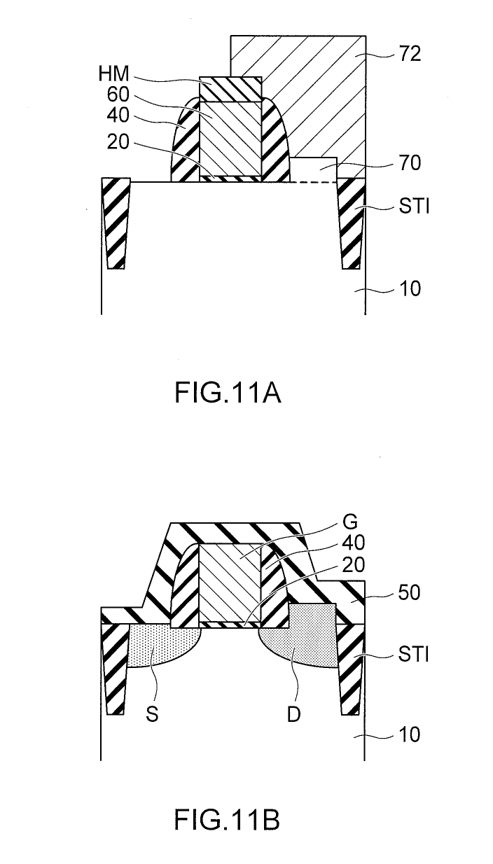

FIGS. 10A to 11B are cross-sectional views of an example of a manufacturing method of the TFET 200 according to the second embodiment. A trench is formed first in the semiconductor layer 10 by the lithographic technique and the etching technique. Next, an insulation film such as a silicon oxide film is embedded into this trench, thereby forming the shallow trench isolation regions STI.

Next, a material for the gate dielectric film 20 is formed on the semiconductor layer 10. Next, a material for the gate electrode G is deposited on the material for the gate dielectric film 20. Next, a material for a hard mask HM is deposited on the material for the gate electrode G. For example, the material for the hard mask HM is a silicon nitride film and the like.

Next, the material for the hard mask HM is processed by the lithographic technique and the etching technique. Further, the material for the gate electrode G and the material for the gate dielectric film 20 are processed by using the hard mask HM as a mask. With this process, the gate electrode G and the gate dielectric film 20 are formed. The hard mask HM on the gate electrode G is also used in a subsequent epitaxial process.

Next, the sidewall film 40 is formed on a side surface of the gate electrode G. As a result, the gate structure GS shown in FIG. 10A is obtained.

Next, as shown in FIG. 10B, an epitaxial layer (for example, a silicon layer) 70 is selectively formed on a region where the source layer S is formed and a region where the drain layer D is formed on the semiconductor layer 10 by epitaxial growth. At this time, the epitaxial layer 70 does not grow on the shallow trench isolation region STI and the hard mask HM. A top surface of the epitaxial layer 70 is located at a position higher than that of an interface between the gate dielectric film 20 and the semiconductor layer 10. It is possible to assume the epitaxial layer 70 to be an integrated semiconductor layer with the semiconductor layer 10.

Next, as shown in FIG. 11A, the region where the drain layer D is formed is covered by a resist film 72 by the lithographic technique. Next, the epitaxial layer 70 formed on the region where the source layer S is formed is removed (recessed) by using the resist film 72 as a mask.

Next, as shown in FIG. 11B, the source layer S, the drain layer D, and the stress layer 50 are formed. Next, as shown in

FIG. 9, the interlayer dielectric film 60 is deposited on the stress layer 50. The source layer S, the drain layer D, the stress layer 50, and the interlayer dielectric film 60 can be formed similarly to those of the first embodiment. Thereafter, contact plugs, wires, other interlayer dielectric films, and the like (not shown) are formed on the interlayer dielectric film 60, thereby completing the TFET 200 shown in FIG. 9.

According to the second embodiment, the interface IFd is formed at a position higher than that of the interface IFs. Accordingly, the boundary (the drain edge) ED between the drain layer D and the channel part CH becomes farther from the stress layer 50 than the boundary (the source edge) ES between the source layer S and the channel part CH. Therefore, a stress applied to the drain layer D is smaller than that applied to the source layer S. Accordingly, the second embodiment can also achieve effects identical to those of the first embodiment.

### Third Embodiment

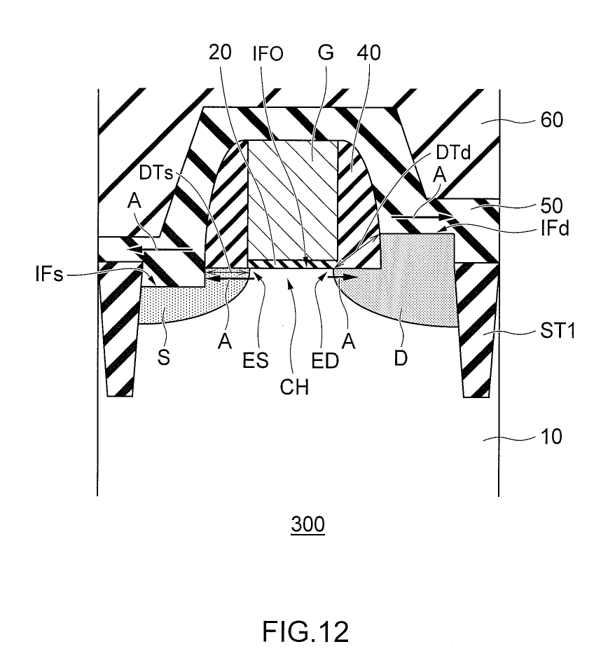

FIG. 12 is a cross-sectional view showing an example of a configuration of a TFET 300 according to a third embodiment. The third embodiment is different from the second embodiment in that the source layer S is recessed from the interface IFO. Because the source layer S is recessed, the area of the interface IFs between the stress layer 50 and the source layer S becomes large and a stress applied by the stress layer 50 to the source layer S also becomes large. That is, a stress applied to the source layer S is much larger than that applied to the drain layer D. As a result, tunneling efficiency on the side of the source layer S that determines an on-state current can be further improved without increasing tunneling efficiency on the side of the drain layer D that determines an off-state current.

The manufacturing method of the TFET 300 according to the third embodiment can be easily understood based on the manufacturing method of the TFET 200 according to the second embodiment. For example, in the etching process of FIG. 11A, not only the epitaxial layer 70 on the source layer S but also a top (a surface region) of the semiconductor layer 10 is removed. As a result, a recess is formed in the source layer S. Other processes of the third embodiment can be identical to corresponding ones of the second embodiment.

### Modification

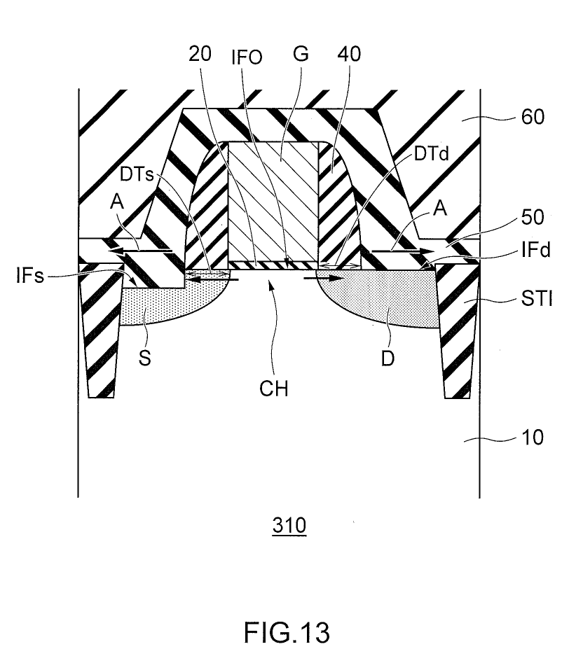

FIG. 13 is a cross-sectional view showing an example of a configuration of a TFET 310 according to a modification of the third embodiment. In the TFET 310, the height of a top surface of the drain layer D (the interface IFd) is equal to that of the interface IFO. Other configurations of the present modification can be identical to those of the TFET 300 according to the third embodiment.

According to the third embodiment, a distance from a boundary between the drain layer D and the channel part CH to the stress layer 50 is substantially equal to a distance from a boundary between the source layer S and the channel part CH to the stress layer 50. That is, the distance DTd is substantially equal to the distance DTs. However, because the source layer S is recessed, the area of the interface IFs between the stress layer 50 and the source layer S is larger than that of the interface IFd between the stress layer 50 and the drain layer D. As the area of an interface with the stress layer 50 becomes large, a stress from the stress layer 50 also becomes large. Therefore, even though the distance DTd is substantially equal to the distance DTs, a stress applied to the source layer S is larger than that applied to the drain layer D. As explained above, even when the source layer S is recessed instead of protruding the drain layer D, tunneling efficiency on the side of the source layer S can be improved without increasing tunneling efficiency on the side of the drain layer D.

The manufacturing method of the present modification can be provided while omitting the process of forming the epitaxial layer 70 shown in FIG. 10B from the manufacturing method according to the third embodiment.

The second embodiment, the third embodiment, or the modification of the third embodiment can be combined with the first embodiment or the modification thereof. With this combination, a stress applied to the drain layer D becomes much smaller than that applied to the source layer S. Therefore, an off-state current can be further suppressed.

In the above embodiments, the N-TFETs 100 to 310 have been explained. However, it is needless to mention that the above embodiments can be applied to a P-TFET. In this case, the source layer S is an n-type diffusion layer and the drain layer D is a p-type diffusion layer.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor layer;
a first conductivity-type first source layer in the semiconductor layer;
a second conductivity-type drain layer in the semiconductor layer;
a gate dielectric film on the semiconductor layer between the first source layer and the drain layer;
a first gate structure on the gate dielectric film;
a drain-side adjacent structure that is adjacent to the first gate structure on a side of the drain layer of the first gate structure; and
a stress layer covering at least the first gate structure, the drain-side adjacent structure, and the first source layer, the stress layer having strain, wherein
a first gap between the first gate structure and the drain-side adjacent structure is narrower than four times a film thickness of the stress layer, and
the stress layer covers the first source layer along a channel direction longer than the first gap.

2. The device of claim 1, wherein a length of the stress layer covering the first source layer along a channel direction is longer than four times the film thickness of the stress layer.

3. The device of claim 1, further comprising a first source-side adjacent structure that is adjacent to the first gate structure on a side of the first source layer of the first gate structure, wherein
a second gap between the first gate structure and the first source-side adjacent structure is wider than the first gap.

4. The device of claim 3, wherein the second gap is wider than four times the film thickness of the stress layer.

5. The device of claim 1, wherein
the drain-side adjacent structure is a second gate structure that shares the drain layer with the first gate structure,
the device further comprises a first conductivity-type second source layer in the semiconductor layer on an opposite side of the drain layer of the second gate structure, and
the stress layer covers the second source layer along a channel direction longer than the first gap.

6. The device of claim 5, further comprising a second source-side adjacent structure that is adjacent to the second gate structure on a side of the second source layer of the second gate structure, wherein
a third gap between the second gate structure and the second source-side adjacent structure is wider than the first gap.

7. The device of claim 6, wherein the third gap is wider than four times the film thickness of the stress layer.

8. The device of claim 3, wherein
the drain-side adjacent structure is a dummy gate structure that is provided above the drain layer and formed of a material same as that for the first gate structure, and
the first source-side adjacent structure is a dummy gate structure that is provided above the first source layer and that is formed of the material same as that for the first gate structure.

9. The device of claim 8, further comprising a dummy gate structure that is adjacent to the drain-side adjacent structure on an opposite side to the first gate structure of the drain-side adjacent structure and that is formed of the material same as that for the first gate structure.

10. The device of claim 1, wherein a stress of the stress layer applied to the first source layer is larger than a stress of the stress layer between the first gate structure and the drain-side adjacent structure.

11. The device of claim 3, wherein a stress of the stress layer between the first gate structure and the first source-side adjacent structure is larger than a stress of the stress layer between the first gate structure and the drain-side adjacent structure.

12. The device of claim 6, wherein a stress of the stress layer between the second gate structure and the second source-side adjacent structure is larger than a stress of the stress layer between the first gate structure and the second gate structure.

13. The device of claim 1, wherein a height of an interface between the drain layer and the stress layer is higher than that of an interface between the first source layer and the stress layer.

14. A semiconductor device comprising:
a semiconductor layer;
a first conductivity-type source layer in the semiconductor layer;
a second conductivity-type drain layer in the semiconductor layer;
a gate dielectric film on the semiconductor layer between the source layer and the drain layer;
a gate structure on the gate dielectric film; and
a stress layer covering the gate structure, the source layer, and the drain layer, the stress layer having strain, wherein
a height of an interface between the drain layer and the stress layer is higher than that of an interface between the source layer and the stress layer.

15. The device of claim 14, wherein
a height of an interface between the drain layer and the stress layer is higher than that of an interface between the semiconductor layer and the gate dielectric film, and
a height of an interface between the source layer and the stress layer is lower than that of an interface between the semiconductor layer and the gate dielectric film.

16. The device of claim 14, wherein
a height of an interface between the drain layer and the stress layer is substantially equal to that of an interface between the semiconductor layer and the gate dielectric film, and
a height of an interface between the source layer and the stress layer is lower than that of an interface between the semiconductor layer and the gate dielectric film.

17. The device of claim 16, wherein an area of an interface between the source layer and the stress layer is larger than that of an interface between the drain layer and the stress layer.

18. The device of claim 14, wherein the drain layer is formed in an epitaxial layer of the semiconductor layer located at a position higher than an interface between the semiconductor layer and the gate dielectric film.

19. The device of claim 15, wherein the source layer is formed in a recess region where a surface region of the semiconductor layer is removed.

20. The device of claim 16, wherein the source layer is formed in a recess region where a surface region of the semiconductor layer is removed.
